(19) United States
(12) Patent Application Publication
(10) Pub. No.: US 2020/0243228 A1
(43) Pub. Date: Jul. 30, 2020

(54) METHOD FOR MANUFACTURING RESISTOR

(71) Applicant: KOA CORPORATION, Ina-shi-Nagano (JP)

(72) Inventors: Soya Miyajima, Ina-shi (JP); Keishi Nakamura, Ina-shi (JP)

(73) Assignee: KOA CORPORATION, Ina-shi, Nagano (JP)

(21) Appl. No.: 16/634,945

(22) PCT Filed: Jul. 11, 2018
(86) PCT No.: PCT/JP2018/026180

§ 371 Date: Jan. 29, 2020

(30) Foreign Application Priority Data
Aug. 10, 2017 (JP) 2017-155152

(51) Int. Cl. H01C 17/07; H01C 17/28; B23K 20/02; G01R 19/00

(52) U.S. Cl. CPC H01C 17/07; H01C 17/28; B23K 2101/36; G01R 19/0092; B23K 20/02

(57) ABSTRACT

Provided is a method for manufacturing a current detection resistor, which can prevent uneven-shaped weld trace from generating on a surface close to the bonded surface between the electrode metal and the resistor metal body in a current detection resistor in which electrode metals are bonded to both ends of the resistor metal body. The method includes preparing electrode metals and a resistor metal; stacking the electrode metal, the resistor metal, and the electrode metal, and applying pressure from the stacked direction to form an integrated resistor base material; applying pressure to the resistor base material from a direction perpendicular to the stacked direction to make the resistor base material a thin plate-shape resistor base material; and, obtaining individual resistors from the thin plate-shape resistor base material. The resistor base material is preferably formed by using a hot pressure bonding process.

### TECHNICAL FIELD

The present invention relates to a method for manufacturing a current detection resistor in which electrode metals are bonded to both ends of a resistor metal body.

### BACKGROUND ART

Recently, current detection resistors used in electronic devices or the like tend to pass a large current through the resistor body. Along with this, the amount of heat generated in the resistor body increases. From the viewpoint of heat dissipation, there is a tendency that resistors, in which electrode metals such as copper are abutted and welded to both ends of the resistor metal body by laser beam welding, electron beam welding, or the like, are increasing. (see Japanese laid-open patent publication 2009-71123)

However, in such current detection resistors, when the resistor metal body and the electrode metal are bonded by welding, uneven-shaped weld trace called a bead is formed on surface of the metal material in the vicinity of the bonded portion. However, upon the current detection resistor, a wire bonding is applied on an electrode metal side in the vicinity of the bonded surface between the resistor metal body and the electrode metal, and a voltage generated across the resistor metal body is detected by the bonded wires.

However, the wire bonding should be applied as close to the bonded surface between the resistor metal and the electrode metal as possible. If a bead (uneven-shaped weld trace) is formed in the vicinity of the bonded surface, there is a problem that the bondability of the wire bonding is deteriorated due to the bead (uneven-shaped weld trace). That is, it is desirable that the electrode surface close to the bonded surface of the current detection resistor is flat.

In order to bond the resistor metal and the electrode metal, a method that the resistor metal and the electrode metal are stacked and heat and/or pressure is applied to perform pressure bonding (cladding), is known (see Japanese laid-open patent publication 2002-57009). Such a method is applicable for stacking a wide surface resistor metal and a wide surface electrode metal. However, application of large pressure is necessary to perform the pressure bonding (cladding), and not applicable for abutting and bonding upon small surfaces together.

### SUMMARY OF INVENTION

### Technical Problem

The invention has been made basing on above-mentioned circumstances. Thus, an object of the invention is to provide a method for manufacturing a current detection resistor, which can prevent uneven-shaped weld trace from generating on a surface close to the bonded surface between the electrode metal and the resistor metal body in a current detection resistor in which electrode metals are bonded to both ends of the resistor metal body.

### Solution to Problem

The method for manufacturing a resistor of the invention includes preparing electrode metals and a resistor metal; stacking the electrode metal, the resistor metal, and the electrode metal, and applying pressure from the stacked direction to form an integrated resistor base material; applying pressure to the resistor base material from a direction perpendicular to the stacked direction to make the resistor base material a thin plate-shape resistor base material; and, obtaining individual resistors from the thin plate-shape resistor base material.

According to the invention, welding such as laser beam welding or electron beam welding is not used to bond the electrode metal and the resistor metal. But, by applying pressure to stacked metals of the electrode metal and the resistor metal, a strong bond between the electrode metal and the resistor metal is formed, and then a current detection resistor is formed. Therefore, bead (uneven-shaped weld trace) cannot be formed on a surface in the vicinity of the bonded surface between the electrode metal and the resistor metal, and the problem that the bondability of wire bonding is deteriorated can be solved.

### BRIEF DESCRIPTION OF DRAWINGS

FIG. 1 is an explanatory view of the starting material of the invention.

FIG. 2 is an explanatory view of first pressure processing of the invention.

FIG. 3 is an explanatory view of second pressure processing of the invention.

FIG. 4 is an explanatory view, which obtains individual resistors from thin plate resistor base material of the invention.

FIG. 5 Left view is a plan view of an obtained resistor, and right view is a sectional view along longitudinal center line of the left view.

FIG. 6A Left view is a plan view of the resistor of modified embodiment, and right view is a sectional view along longitudinal center line of the left view.

FIG. 6B Left view is a plan view of the resistor of the other modified embodiment, and the right view is a sectional view along longitudinal center line of the left view.

FIG. 7A As to a resistor in which entire surface thereof is plated, left view is a plan view, and right view is a sectional view along longitudinal center line of the left view.

FIG. 7B As to a resistor in which entire surface thereof is plated, left view is a plan view, and right view is a sectional view along longitudinal center line of the left view.

FIG. 8A As to a resistor in which only electrode surface portion thereof is plated, left view is a plan view, and right view is a sectional view along longitudinal center line of the left view.

FIG. 8B As to a resistor in which only electrode surface portion thereof is plated, left view is a plan view, and right view is a sectional view along longitudinal center line of the left view.

### DESCRIPTION OF EMBODIMENTS

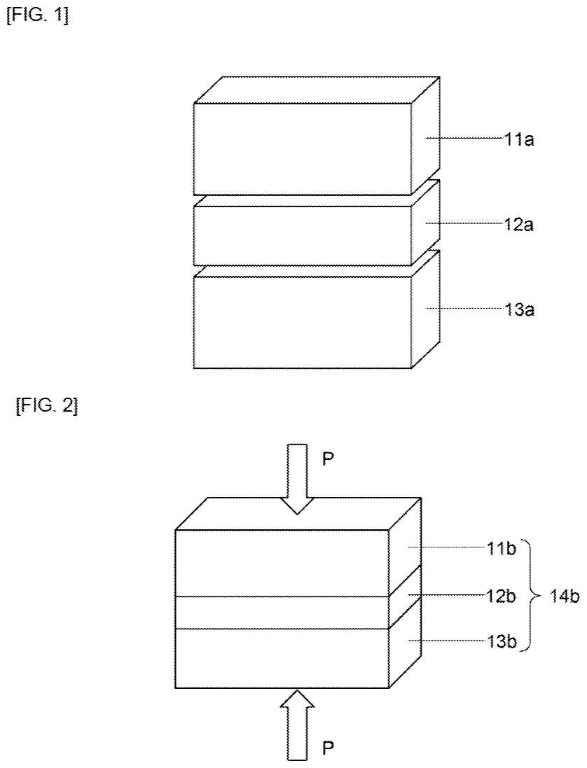

Embodiments of the present invention will be described below with referring to FIG. 1 through FIG. 8B. In the figures, the same or corresponding members or elements will be described with the same reference characters.

FIG. 1 shows a preparation stage of starting materials of the invention. That is, electrode metals 11a and 13a and a resistor metal 12a are prepared. The electrode metals 11a and 13a are preferably copper material having good electrical conductivity and thermal conductivity. The resistor metal 12a is preferably resistance alloy material such as copper/manganese/nickel alloy, nickel/chromium alloy, or copper/nickel alloy having a small specific resistance and a small temperature coefficient of resistance (TCR).

In order to enable continuous production of the individual resistors, the electrode metals 11a and 13a and the resistor metal 12a are preferable to use long materials. As an example, a preferable cross-sectional dimension of the electrode metals 11a and 13a is a width of about 0.5 to 5.0 mm and a height (thickness) of about 0.2 to 3.0 mm. A preferable cross-sectional dimension of the resistor metal 12a is a width of about 0.5 to 5.0 mm and a height (thickness) of about 0.5 to 5.0 mm.

FIG. 2 shows a stage in which the electrode metal 11a, the resistor metal 12a, and the electrode metal 13a are stacked, and by pressure bonding process, that is, by applying pressure P from the stacked direction, an integrated resistor base material 14b is formed. The pressure bonding process includes hot pressure bonding process in which heat of about 750 to 850° C. and pressure are applied, and cold pressure welding process in which only pressure is applied at room temperature. However, the hot pressure bonding, in which the materials are heated and compressed, is preferable because a good bonding can be formed at a low pressure.

The integrated resistor base material 14b made of the compressed electrode metal 11b, the resistor metal 12b, and the electrode metal 13b is formed by above-described hot pressure bonding process. At the interface between the electrode metals 11b and 13b and the resistor metal 12b, a strong diffusion bonding, in which mutual atoms diffuse each other, is formed. In the vertical direction (stacked direction), the resistor base material 14b is compressed by about 0 to 40%, and the height of the resistor base material 14b is about 0.5 to 11 mm, and in the horizontal direction (direction perpendicular to the stacked direction), the resistor base material 14b is expanded by about 0 to 40%, and the width of the resistor base material 14b is about 0.5 to 7 mm.

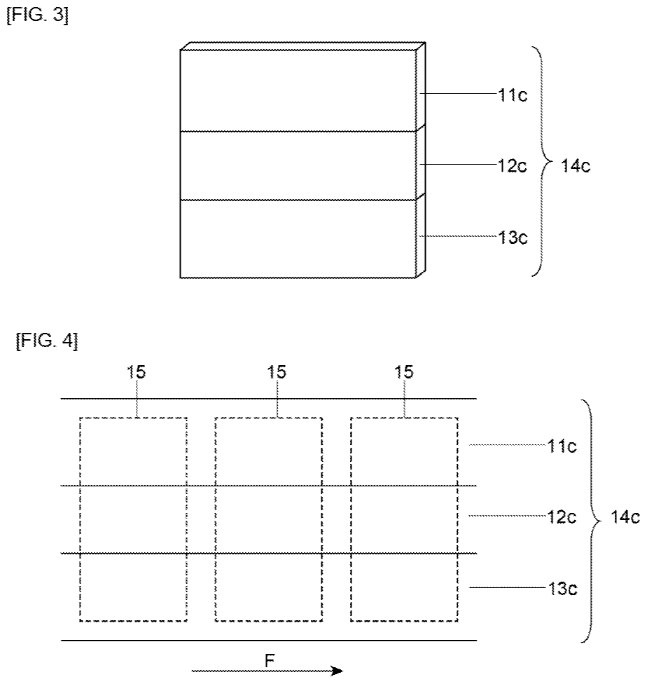

FIG. 3 shows a stage, in which the resistor base material 14b is flattened by applying pressure from a direction perpendicular to the stacked direction to form a thin plate-shape resistor base material 14c. The thin plate-shape is a state, in which the thickness is reduced as compared with the resistor base material 14b in the previous stage. In this stage of processing, the resistor base material 14b is rolled to a final thickness of about 0.2 to 3 mm through a plurality of rollers at room temperature. The rolling direction can be controlled. Rolling in the length direction of the resistor base material 14c without changing the height of the resistor base material 14c, and adjusting the width (thickness) of the resistor base material 14c to the final thickness of the individual resistor, are possible.

At this stage, the electrode metals 11b and 13b and the resistor metal 12b are compressed to the thickness of the electrode metals 11c and 13c and the resistor metal 12c, which are the final resistor dimensions.

FIG. 4 shows a stage of obtaining individual resistors 15 as final products from flattened thin plate-shape resistor base material 14c. Individual resistors 15 can be obtained by punching out from the resistor base material 14c with a press. Since the thickness of the individual resistor 15 is determined by the thickness of the resistor base material 14c as described above, the length and width of the individual resistor 15 are determined by punching dimensions of the press.

It is preferable that punching position of the press is fixed, and the individual resistor 15 is punched out at each section of the long resistor base material 14c while moving along the moving direction (arrow F). As a result, by preparing the long electrode metals 11a, 13a and the long resistor metal 12a, the above-mentioned “first pressure bonding process of forming an integrated resistor base material 14b, in which electrode metal 11a, resistor metal 12a, and electrode metal 13a are stacked and integrally bonded by applying pressure from the stacked direction”, and “second pressure applying process of forming a flattened thin plate-shape resistor base material 14c by applying pressure from a direction perpendicular to the stacked direction”, then it becomes possible to continuously produce the individual resistors 15 from long size materials.

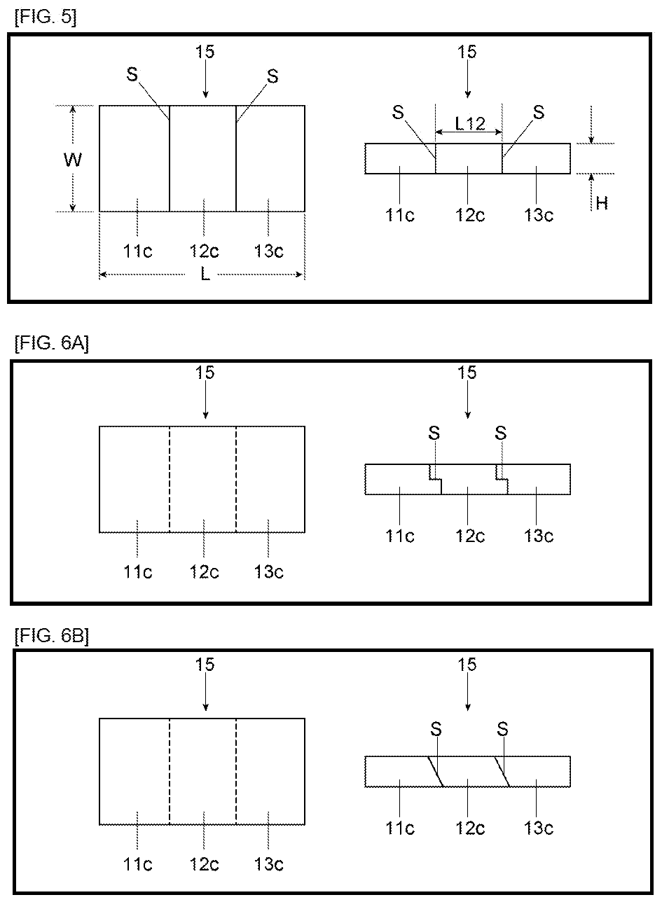

FIG. 5 shows an example of the structure of the individual resistor 15 obtained by above-mentioned process. The compressed electrode metals 11c and 13c are fixed to both ends of the compressed resistor metal body 12c by pressure bonding. The bonded surface S is a diffusion bonding surface in which both atoms diffuse to each other, whereby the resistor metal 12c and the electrode metals 11c and 13c are strongly fixed, and excellent electrical characteristics can be obtained. Since so-called welding is not used, then the electrode surface is a smooth flat surface, where bead (uneven-shaped weld trace) cannot be formed.

For example, when measuring a current of 400 to 500 A, if the resistance value is 0.1 mΩ, the outer dimensions are 10 mm (L)×10 mm (W)×0.5 mm (H), and the resistor length (L12) 1.5 mm is appropriate. Further, when it is desired to measure a current of 200 to 300 A, if the resistance value is 0.2 mΩ, the outer dimensions are 10 mm (L)×10 mm (W)×0.25 mm (H), and the resistor length (L12) 1.5 mm is appropriate.

FIG. 6A and FIG. 6B show modified embodiments of the invention. The bonded surface S between the resistor metal 12c and the electrode metal 11c or 13c in cross section shows examples of shapes, which has wider bonded surface S than the bonded surface S consisting of thickness of each metal 11c, 12c, 13c.

That is, in the embodiment shown in FIG. 5, the length in cross section of the bonded surface S is formed equal to thickness of each metal. However, in FIG. 6A, the length in cross section of the bonded surface S is formed in a crank shape, and in FIG. 6B, the length in cross section of the bonded surface S is formed in an inclined shape. Therefore, the area in cross section of the bonded surface S in FIGS. 6A and 6B is wider than the area in cross section of the bonded surface S in FIG. 5. As a result, the bonding strength of the bonded surface S in FIGS. 6A and 6B increases, and it can be possible to maintain good bonding state even when pressure is applied from vertical and horizontal directions of the resistor.

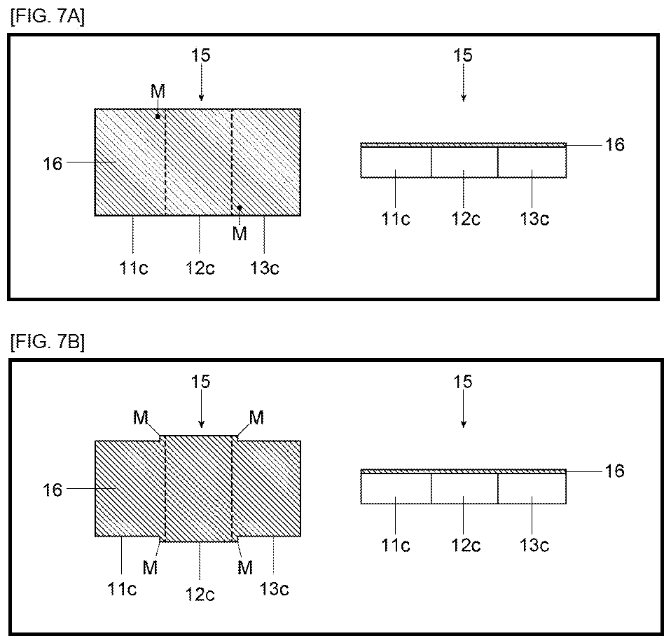

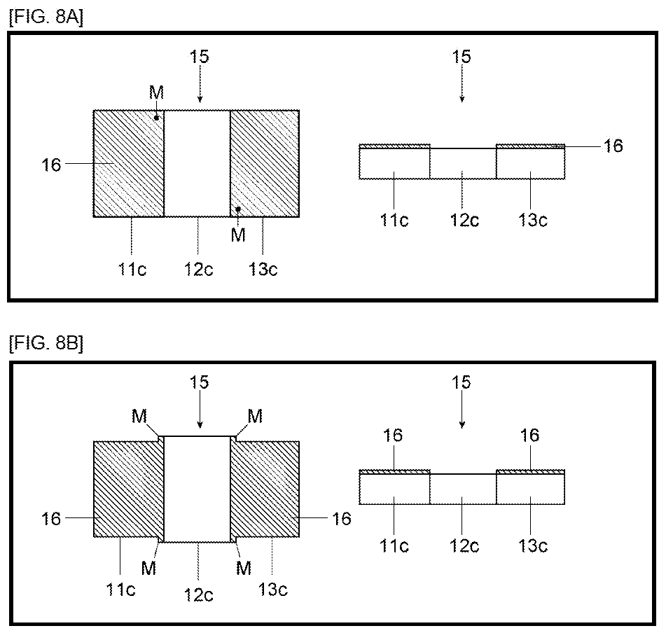

FIG. 7A and FIG. 7B show another modified embodiment of the invention, and show examples in which wire bonding positions on electrode metal portions when mounting are indicated. According to the invention, since the surface of the resistor 15 is covered by plated layer 16, boundary between the resistor 12c and the electrode 11c or 13c is difficult to identify.

Therefore, it is preferable to provide a mark M indicating the wire bonding position. As a method for forming the mark M, concave portions are formed by punching as shown in FIG. 7A, or protrusions or the like are formed on the outer peripheral surface of the resistor 15 as shown in FIG. 7B. The plated layer 16 can be formed before the punching step shown in FIG. 4 by plating an alloy film such as Ni—P or Ni—P—W on one surface of the resistor base material 14c, using such as electroplating method or electroless-plating method. In the example, forming a plated layer only on one surface to be wire-bonded is shown, but another plated layer may be formed on another surface.

FIG. 8A and FIG. 8B show another modified embodiment of FIG. 7A and FIG. 7B. That is, the plated layers 16 are formed only on the electrode portions 11c and 13c, and the plated layer 16 is not formed on the resistor portion 12c. The plated layers 16 in the embodiment can be formed by masking the resistor 12c in advance, forming the plated layer 16 by the above-described method, and then removing the mask to form the plated layers 16 only on the electrode portions 11c and 13c. Also in these examples, concave portions M are formed by punching as shown in FIG. 8A, or protrusions or the like are formed on the outer peripheral surface of the resistor 15 as shown in FIG. 8B to provide marks M for indicating wire bonding positions. Thereby, mounting of the resistor 15 becomes easy.

Although embodiments of the invention has been described, it is needless to say that the invention is not limited to the above-described embodiments, and may be implemented in various forms within the scope of the technical concept of the invention.

### INDUSTRIAL APPLICABILITY

The invention can be suitably applicable for the current detection resistors that detects a large current with high accuracy.

1. A method for manufacturing a resistor, comprising:
preparing electrode metals and a resistor metal;
stacking the electrode metal, the resistor metal, and the electrode metal, and applying pressure from stacked direction to form an integrated resistor base material,
applying pressure to the resistor base material from a direction perpendicular to the stacked direction to make the resistor base material a thin plate-shape resistor base material; and,
obtaining individual resistors from the thin plate-shape resistor base material.

2. The method of claim 1, wherein the resistor base material is formed by using hot pressure bonding process.

3. The method of claim 1, wherein an area of the bonded surface between the resistor metal and the electrode metal is wider than the area of thickness of each metal.

4. The method of claim 1, wherein a wire bonding position on an electrode metal portion when mounting is indicated.
